(19) United States
(12) Patent Application Publication
(10) Pub. No.: US 2010/0086097 A1
(43) Pub. Date: Apr. 8, 2010

(54) SHIFT REGISTER CIRCUIT AND DISPLAY MODULE

(75) Inventors: Ming-Chun TSENG, Tainan County (TW); Tsung-Chien TSAI, Tainan County (TW); Yu-Wen CHIOU, Tainan County (TW); Hong-Ru GUO, Tainan County (TW)

Correspondence Address: LOWE HAUPTMAN HAM & BERNER, LLP, 1700 DIAGONAL ROAD, SUITE 300, ALEXANDRIA, VA, 22314, US

(73) Assignees: CHI MEI EL CORP., Tainan County (TW); CHI MEI OPTOELECTRONICS CORP., Tainan County (TW)

(21) Appl. No.: 12/574,000

(22) Filed: Oct. 6, 2009

(30) Foreign Application Priority Data
Oct. 6, 2008 (TW) 97138426

(51) Int. Cl. G11C 19/00; G09G 5/00

(52) U.S. Cl. 377/79; 345/205

(57) ABSTRACT

A shift register circuit includes a latch unit, a leakage current control unit, and a first output unit. The latch unit outputs a latch signal in accordance with a clock signal and an input signal. The first output unit outputs an output signal in accordance with the latch signal. The leakage current control unit is electrically connected between the latch unit and the first output unit for outputting the latch signal to the first output unit in accordance with the clock signal.

### CROSS REFERENCE TO RELATED APPLICATIONS

This Non-provisional application claims priority under 35 U.S.C. §119(a) on Patent Application No(s). 097138426 filed in Taiwan, Republic of China on Oct. 6, 2008, the entire contents of which are hereby incorporated by reference.

### BACKGROUND

1. Technical Field

The present disclosure relates to a shift register circuit and a display module.

2. Related Art

From the early CRT (Cathode Ray Tube) display devices to the present LCD (Liquid Crystal Display) devices, OLED (Organic Light-Emitting Diode) display devices and E-paper display devices, the display devices have been greatly reduced in volume and weight. This also facilitates such flat panel display devices to be widely used in many applications such as communication products, information products and consumer electronics products.

In general, a flat panel display device has a display module, which usually includes a display panel and a shift register circuit. The shift register circuit can be electrically connected with a data line driving circuit or a scan line driving circuit for controlling the display panel. In the following description/illustration, the shift register circuit is electrically connected with the scan line driving circuit, for example.

As shown in FIG. 1, a known shift register circuit 1 includes a latch unit 11, a first output unit 12 and a second output unit 13. The first output unit 12 is electrically connected with the latch unit 11 and the second output unit 13.

The latch unit 11 has a transistor T₁₁, and the first output unit 12 has a transistor T₁₂. The first end of the transistor T₁₁ is electrically connected with the gate of the transistor T₁₂. In this case, the transistors T₁₁ and T₁₂ are both P-type transistors.

The second output unit 12 has a transistor T₁₃, a transistor T₁₄ and a transistor T₁₅. The gate of the transistor T₁₅ is electrically connected with first ends of the transistors T₁₃ and T₁₄, and a first end of the transistor T₁₅ is electrically connected with a first end of the transistor T₁₂ and the gate of the transistor T₁₃.

Referring to FIG. 2, during a first time period t₁₁, an input signal A₁₁ and a clock signal CK₁₁ are both in a low-voltage level, and the transistors T₁₁ and T₁₄ are turned on. The transistor T₁₁ outputs a latch signal A₁₂ in accordance with the input signal A₁₁ to the gate of the transistor T₁₂. The latch signal A₁₂ controls the transistor T₁₂ to turn on, so that the first, output end O₁ outputs a to-be-outputted signal A₁₃ received at the second end.

In addition, a ground voltage Vₛₛ is applied to the gate of the transistor T₁₅ through the transistor T₁₄, so that the gate voltage A₁₄ of the transistor T₁₅ is in the low-voltage level, thereby turning on the transistor T₁₅.

During a second time period t₁₂, the input signal A₁₁ and clock signal CK₁₁ are both in a high-voltage level, so that the transistors T₁₁ and T₁₄ are turned off and the transistor T₁₂ is still turned on. In this case, since the to-be-outputted signal A₁₃ at the second end of the transistor T₁₂ is changed from the high-voltage level (e.g. +5V) to the low-voltage level (e.g. −5V) and a parasitic capacitance exists between the second end and the gate of the transistor T₁₂, the latch signal A₁₂ is changed from the low-voltage level (e.g. −3V) to a much lower voltage level (e.g. −13V). Meanwhile, the output end O₁ is changed from the high-voltage level (e.g. +5V) to the low-voltage level (e.g. −5V).

In this case, during the second time period t₁₂, the first end of the transistor T₁₁ is −13V, and the second end thereof is +5V. Thus, the voltage difference between the first and second ends of the transistor T₁₁ is 18V.

However, the voltage difference between the first and second ends of the transistor may lead to the leakage current of the transistor. Moreover, the leakage current may increase as the voltage difference increases. As shown in FIG. 2, if the leakage current issue of the transistor T₁₁ becomes worse, the voltage of the first end of the transistor T₁₁ increases (as shown by the dotted line for the latch signal A₁₂). That is, the voltage of the gate of the transistor T₁₂ becomes smaller, which may result in the turn-off of the transistor T₁₂. Accordingly, the waveform of the outputted signal O₁ is improper (as shown by the dotted line for the voltage level in the output end O₁), so that the scan signal O₁ transmitted to the display panel cannot completely turn on the transistors of the pixels. In this case, the data voltage cannot be written into each pixel accurately, so that the image may not be displayed correctly. Therefore, there is a need to provide a shift register circuit and display module that can improve the leakage current issue of the transistors.

### SUMMARY

In one or more embodiments, a shift register circuit comprises a latch unit, a first output unit and a leakage current control unit. The latch unit is for generating a latch signal in accordance with a clock signal and an input signal. The first output unit is for outputting an output signal in accordance with the latch signal. The leakage current control unit is electrically connected between the latch unit and the first output unit for outputting the latch signal to the first output unit in accordance with the clock signal.

In one or more embodiments, a display module comprises a display panel including at least a data line and at least a scan line, and a driving circuitry having a shift register circuit with an output electrically connected with the data line or the scan line of the display panel. The shift register circuit comprises a latch unit, first and second output units and a leakage current control unit. The latch unit is for generating a latch signal in accordance with a clock signal and an input signal. The first output unit is for outputting an output signal at said output in accordance with the latch signal. The second output unit is electrically connected with the first output unit for controlling the output signal at said output in accordance with the clock signal. The leakage current control unit is electrically connected between the latch unit and the first output unit for outputting the latch signal to the first output unit in accordance with the clock signal.

In one or more embodiments, a shift register circuit comprises an input transistor, an output transistor and at least a first transistor. The input transistor comprises a control terminal controllable by a clock signal, a first terminal for receiving an input signal, and a second terminal for outputting a latch signal in accordance with the clock signal and the input signal. The output transistor comprises a control terminal controllable by the latch signal, a first terminal for receiving an intended output signal, and a second terminal for outputting an output signal in accordance with the latch signal and the intended output signal. The first transistor comprises a control terminal controllable by the clock signal, and first and second terminals electrically connected between the second terminal of the input transistor and the control terminal of the output transistor, for supplying the latch signal from the second terminal of the input transistor to the control terminal of the output transistor in a first time period of the clock signal, and for electrically isolating the second terminal of the input transistor from the control terminal of the output transistor in a second time period of the clock signal.

### BRIEF DESCRIPTION OF THE DRAWINGS

FIG. 1 is a schematic diagram of a known shift register circuit;

FIG. 2 is a timing chart of the known shift register circuit;

FIG. 3 is a schematic diagram of a shift register circuit according to one or more embodiments;

FIG. 4 is a timing chart of the shift register circuit of FIG. 3;

FIGS. 5 to 7 are schematic diagrams showing shift register circuits according to various embodiments; and

FIG. 8 is a schematic diagram of a display module according to one or more embodiment.

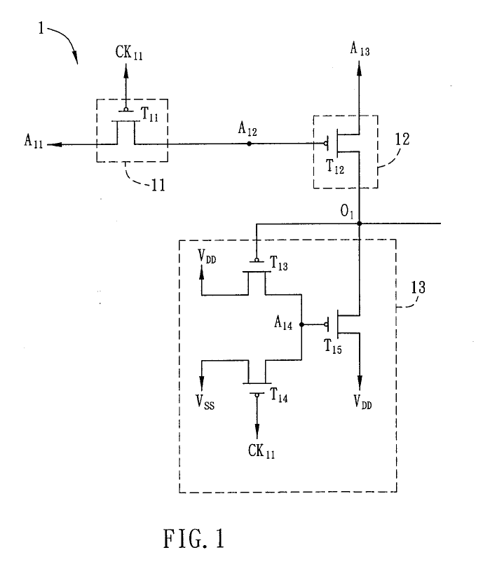

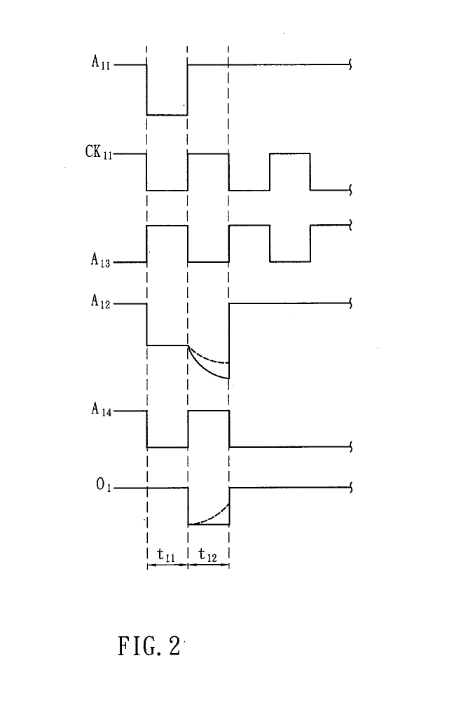

### DETAILED DESCRIPTION

In the accompanying drawings, the same reference numerals relate to the same elements.

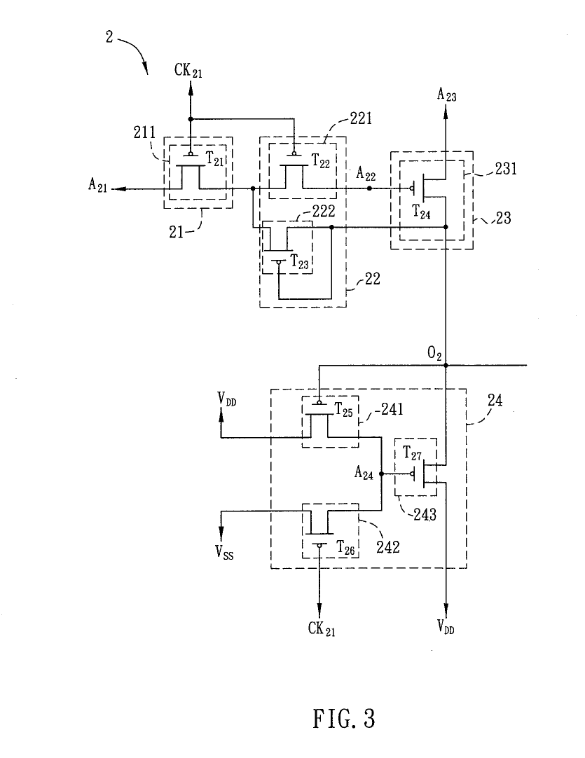

With reference to FIG. 3, a shift register circuit 2 according to one or more embodiments includes a latch unit 21, a leakage current control unit 22, a first output unit 23, and a second output unit 24. The leakage current control unit 22 is electrically connected with the latch unit 21 and the first output unit 23, and the first output unit 23 is further electrically connected with the second output unit 24.

The latch unit 21 has a first switch 211, and the leakage current control unit 22 has a second switch 221 and a third switch 222. The first, second and third switches 211, 221 and 222 are electrically connected with each other.

The first output unit 23 has a fourth switch 231 electrically connected with the second and third switches 221 and 222. The second output unit 24 has a fifth switch 241, a sixth switch 242 and a seventh switch 243. The fifth switch 241 and the seventh switch 243 are respectively electrically connected with the fourth switch 231, and the sixth switch 242 is electrically connected with the seventh switch 243.

In the exemplarily disclosed embodiment, the first switch 211 is a transistor T₂₁, the second switch 221 is a transistor T₂₂, the third switch 222 is a transistor T₂₃, the fourth switch 231 is a transistor T₂₄, the fifth switch 241 is a transistor T₂₅, the sixth switch 242 is a transistor T₂₆, and the seventh switch 243 is a transistor T₂₇.

The gate of the transistor T₂₂ is electrically connected with the gate of the transistor T₂₁, the first end of the transistor T₂₂ is electrically connected with the second end of the transistor T₂₁ and the first end of the transistor T₂₃, and the second end of the transistor T₂₂ is electrically connected with the gate of the transistor T₂₄. The gate of the transistor T₂₃ is electrically connected with the second ends of the transistors T₂₃ and T₂₄. The gate of the transistor T₂₇ is electrically connected with the second end of the transistors T₂₅ and the first end of the transistor T₂₆, and the first end of the transistor T₂₇ is electrically connected with the gate of the transistor T₂₅ and the second end of the transistor T₂₄.

Although in the exemplarily disclosed embodiment, each of the switches comprises a transistor, for example, it can comprise more than one transistors and/or be replaced by any device or devices with a controllable switching function.

In addition, although the transistors T₂₁ to T₂₇ are in the exemplarily disclosed embodiment all PMOS (P-type metal oxide semiconductor) transistors or equivalents, for example, all or some of them can be NMOS (N-type metal oxide semiconductor) transistors or equivalents.

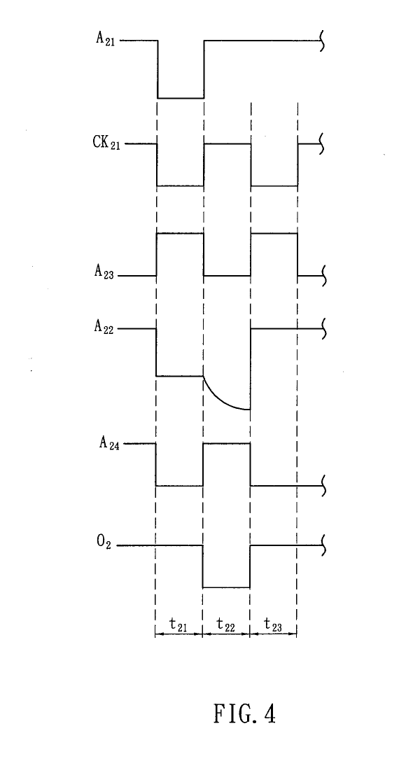

Referring to FIG. 4, during a first time period t₂₁, an input signal A₂₁ and a clock signal CK₂₁ are both in a low-voltage level, and a to-be-outputted signal or intended output signal A₂₃ (which, in some embodiments is a second clock signal being the reverse of CK21) is in a high-voltage level, so that the transistors T₂₆, T₂₁ and T₂₂ are turned on. In this particularly disclosed case, the low-voltage level can be −5V and the high-voltage level can be +5V, for example.

The first switch 211 and the leakage current control unit 22 transform the input signal A₂₁ into a latch signal A₂₂, which is then transmitted to the gate of the transistor T₂₄ so as to turn on the transistor T₂₄.

In addition, a low voltage, e.g., ground voltage, Vₛₛ is applied to the gate of the transistor T₂₇ through the transistor T₂₆, so that the gate voltage A₂₄ of the transistor T₂₇ is in the low-voltage level so as to turn on the transistor T₂₇. At this moment, the output end O₂ outputs a high-voltage level.

During a second time period t₂₂, the input signal A₂₁ and the clock signal CK₂₁ are both in the high-voltage level, and the to-be-outputted signal A₂₃ is in the low-voltage level. In this case, the transistors T₂₁, T₂₂ and T₂₆ are turned off, while the transistors T₂₃ and T₂₄ are turned on. Meanwhile, the output end O₂ outputs a low-voltage level which turns on the transistor T₂₅ so as to make the gate voltage A₂₄ of the transistor T₂₇ reach the high-voltage level.

Since the to-be-outputted signal A₂₃ is changed from the high-voltage level (e.g., +5V) to the low-voltage level (e.g., −5V) and a parasitic capacitance exists between the second end and the gate of the transistor T₂₄, the latch signal A₂₂ is changed from the low-voltage level (e.g., −3V) to a lower voltage level (e.g., −13V). As the gate voltage of the transistor T₂₄ becomes lower, the transistor T₂₄ is ensured to remain in the turned-on state. Therefore, the waveform of the to-be-outputted signal A₂₃ can be accurately transmitted to the output end O₂ through the turned-on transistor T₂₄.

Then, during a third time period t₂₃, the input signal A₂₁ and the to-be-outputted signal A₂₃ are both in the high-voltage level, and the clock signal CK₂₁ is in the low-voltage level. In this case, the transistors T₂₁, T₂₂ and T₂₆ are turned on.

The input signal A₂₁ passes through the first switch 211 and the second switch 221 to turn off the transistor T₂₄. In addition, the ground voltage Vₛₛ is applied to the gate of the transistor T₂₇ through the turned-on transistor T₂₆, so that the gate voltage A₂₄ of the transistor T₂₇ is in the low-voltage level so as to turn on the transistor T₂₇. At this moment, the output end O₂ outputs a high-voltage level in accordance with a high-voltage level V_{DD} transmitted through T₂₇.

As mentioned above, in the shift register circuit 2 of the exemplarily disclosed embodiment, the gate of transistor T₂₂ is +5V, the first end thereof is −3V and the second end thereof is −13V during the second time period t₂₂. Thus, the voltage difference between the first and second ends of the transistor T₂₂ is only 10V. Likewise, the gate of transistor T₂₁ is +5V, the first end thereof is +5V and the second end thereof is −3V during the second time period t₂₂. Thus, the voltage difference between the first and second ends of the transistor T₂₁ is only 8V. Compared with the known device where the voltage difference between the first and second ends of the transistor T₁₁ can reach 18V, the shift register circuit 2 of the exemplarily disclosed embodiment can efficiently reduce the voltage difference between the first and second ends of the transistor T₂₁, thereby improving the leakage current issue. Accordingly, the voltage level of the gate of the transistor T₂₄ can be maintained, so that the outputted waveform at the output end O₂ can be kept accurate.

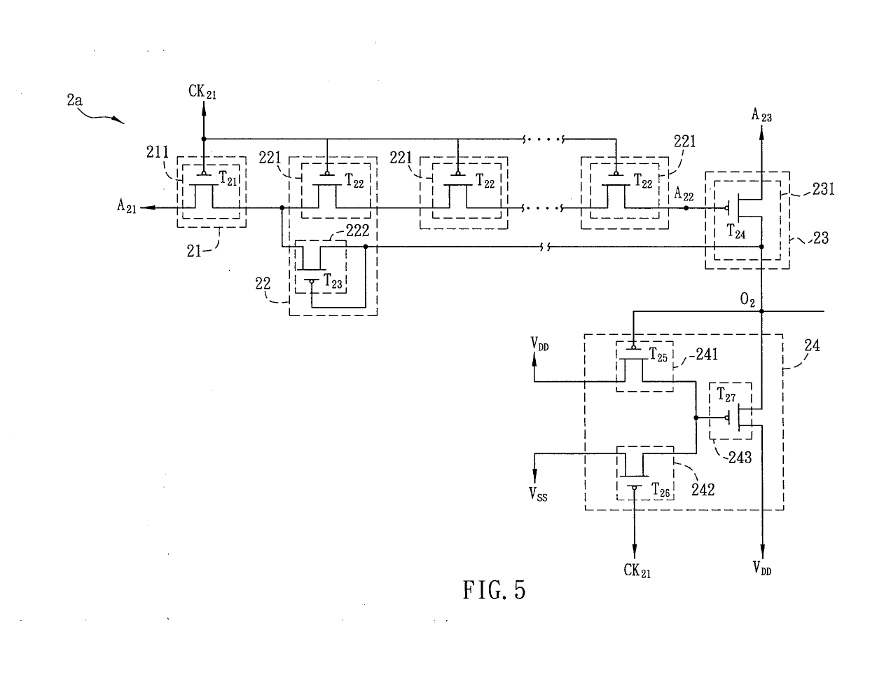

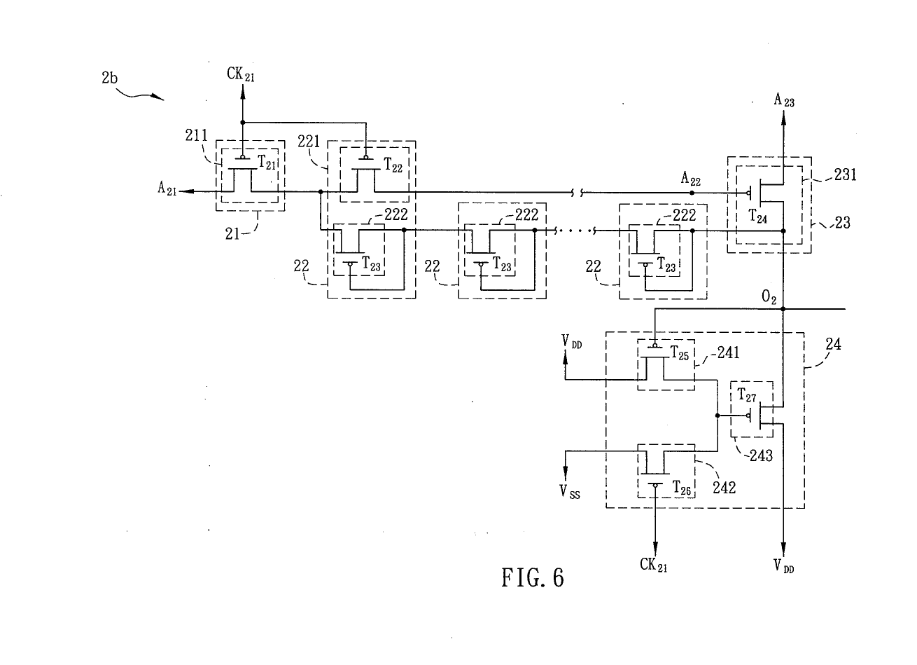

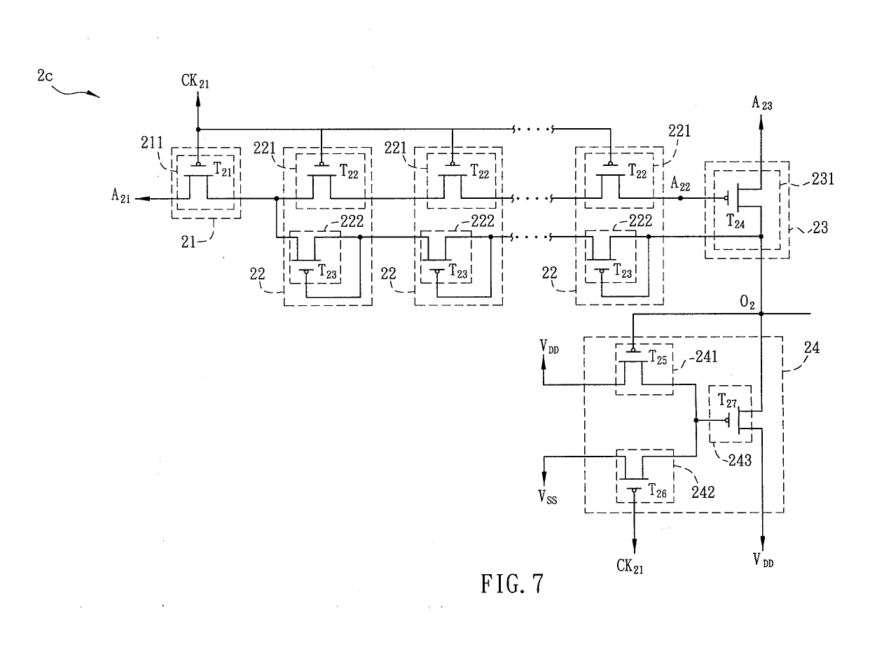

With reference to FIG. 5, a shift register circuit 2a of another embodiment includes a plurality of second switches 221, which are connected in series. Alternatively, referring to FIG. 6, a shift register circuit 2b of yet another embodiment includes a plurality of third switches 222, which are connected in series. Alternatively, referring to FIG. 7, a shift register circuit 2c of still another embodiment includes a plurality of second switches 221, which are connected in series, and a plurality of third switches 222, which are connected in series.

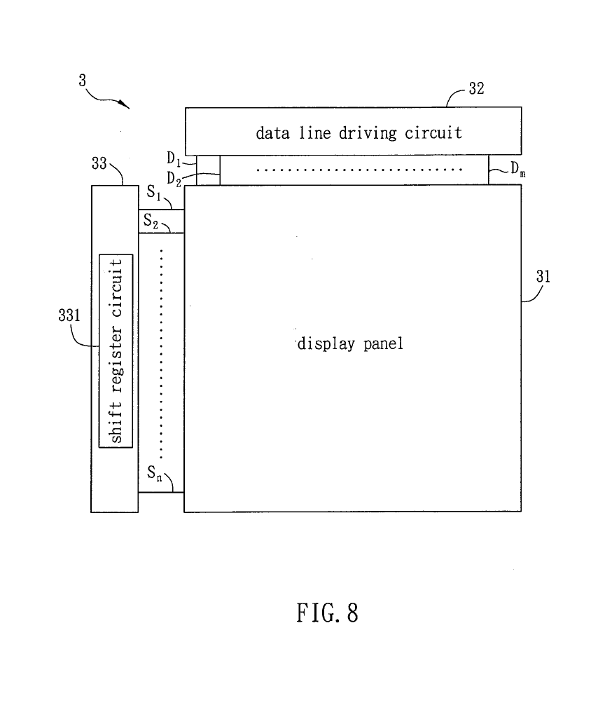

With reference to FIG. 8, a display module 3 according to one or more embodiments includes a display panel 31 and a driving circuitry. In this embodiment, the driving circuitry may include a data line driving circuit 32 and/or a scan line driving circuit 33. The data line driving circuit 32 is electrically connected with the display panel 31 through a plurality of data lines D₁ to Dₘ, and the scan line driving circuit 33 is electrically connected with the display panel 31 through a plurality of scan lines S₁ to Sₙ.

In the particularly disclosed embodiment, the scan line driving circuit 33 includes a shift register circuit 331, which comprises at least one of the shift register circuit 2 as disclosed above with respect to FIGS. 3, 5, 6 and 7, for example. Of course, at least one shift register circuit as disclosed above with respect to FIGS. 3, 5, 6 and 7, can also, for example but not limited to, be configured in the data line driving circuit 32.

Where shift register circuit 331 comprises more than one shift register circuits 2 as exemplarily disclosed above with respect to FIGS. 3, 5, 6 and 7, the shift register circuits 2 are serially connected as disclosed in U.S. Pat. No. 7,573,971 which is incorporated by reference herein in its entirety. Specifically, the output end of each shift register circuit 2 is connected to a corresponding data line or scanning line, and also to the input of the subsequent shift register circuit 2. The input of the first shift register circuit 2 in the series is coupled to receive the input signal A₂₁ from a controller (not shown). In some embodiments, a second clock signal which is the inverse of the clock signal CK₂₁ is inputted as the to-be-outputted signal to all shift register circuits 2 in the series.

In summary, in the exemplarily disclosed shift register circuits and display modules, a leakage current control unit is included to decrease the voltage difference between the first and second ends of the input transistor, so that the leakage current issue can be improved. Furthermore, the operations of the output transistors can be improved so as to output an accurate waveform.

Although several embodiments have been described with specific details, this description is not meant to be construed in a limiting sense. Various modifications of the disclosed embodiments, as well as alternative embodiments, will be apparent to persons skilled in the art.

1. A shift register circuit, comprising:
a latch unit for generating a latch signal in accordance with a clock signal and an input signal;
a first output unit for outputting an output signal in accordance with the latch signal; and
a leakage current control unit electrically connected between the latch unit and the first output unit for outputting the latch signal to the first output unit in accordance with the clock signal.

2. The shift register circuit according to claim 1, wherein the latch unit comprises:
a first switch electrically connected with the leakage current control unit.

3. The shift register circuit according to claim 2, wherein the first switch comprises a transistor.

4. The shift register circuit according to claim 2, wherein the leakage current control unit comprises:
at least one second switch controllable to be on or off by the clock signal; and
at least one third switch electrically connected with the second switch.

5. The shift register circuit according to claim 4, wherein each of the second switch and the third switch comprises a transistor.

6. The shift register circuit according to claim 4, wherein the leakage current control unit comprises a plurality of said second switches, which are connected in series.

7. The shift register circuit according to claim 4, wherein the leakage current control unit comprises a plurality of said third switches, which are connected in series.

8. The shift register circuit according to claim 1, wherein the first output unit comprises:
a fourth switch electrically connected with the leakage current control unit.

9. The shift register circuit according to claim 8, wherein the fourth switch comprises a transistor.

10. The shift register circuit according to claim 1, further comprising a second output unit electrically connected with the first output unit for controlling the output signal in accordance with the clock signal, wherein the second output unit comprises:
a fifth switch electrically connected with the first output unit;
a sixth switch electrically connected with the fifth switch and controllable to be on or off by the clock signal; and
a seventh switch electrically connected with the first output unit, the fifth switch and the sixth switch.

11. A display module, comprising:
a display panel including at least a data line and at least a scan line; and
a driving circuitry having a shift register circuit with an output electrically connected with the data line or the scan line of the display panel, wherein the shift register circuit comprises:
a latch unit for generating a latch signal in accordance with a clock signal and an input signal,
a first output unit for outputting an output signal at said output in accordance with the latch signal,
a second output unit electrically connected with the first output unit for controlling the output signal at said output in accordance with the clock signal, and
a leakage current control unit electrically connected between the latch unit and the first output unit for outputting the latch signal to the first output unit in accordance with the clock signal.

12. The display module according to claim 11, wherein the driving circuitry comprises at least one of a scan line driving circuit and a data line driving circuit, and wherein said at least one of the scan line driving circuit and the data line driving circuit comprises said shift register circuit.

13. A shift register circuit, comprising:
an input transistor comprising
a control terminal controllable by a clock signal,
a first terminal for receiving an input signal, and
a second terminal for outputting a latch signal in accordance with the clock signal and the input signal;
an output transistor comprising
a control terminal controllable by the latch signal,
a first terminal for receiving an intended output signal, and
a second terminal for outputting an output signal in accordance with the latch signal and the intended output signal; and
at least a first transistor comprising
a control terminal controllable by the clock signal, and
first and second terminals electrically connected between the second terminal of the input transistor and the control terminal of the output transistor, for supplying the latch signal from the second terminal of the input transistor to the control terminal of the output transistor in a first time period of the clock signal, and for electrically isolating the second terminal of the input transistor from the control terminal of the output transistor in a second time period of the clock signal.

14. The shift register circuit according to claim 13, further comprising:
at least a second transistor comprising
a control terminal controllable by the output signal, and
first and second terminals electrically connected between the second terminal of the input transistor and the second terminal of the output transistor.

15. The shift register circuit according to claim 14, wherein the first terminal of the second transistor is electrically connected to the control terminal thereof.

16. The shift register circuit according to claim 15, wherein:
the second terminal of the first transistor is electrically connected to the control terminal of the output transistor;
the second terminal of the second transistor is electrically connected to the second terminal of the input transistor; and
the control terminals of the input transistor and the first transistor are commonly coupled to receive the clock signal.

17. The shift register circuit according to claim 15, comprising multiple said first transistors electrically connected in series between the second terminal of the input transistor and the control terminal of the output transistor.

18. The shift register circuit according to claim 17, comprising multiple said second transistors electrically connected in series between the second terminal of the input transistor and the second terminal of the output transistor.

19. The shift register circuit according to claim 15, comprising multiple said second transistors electrically connected in series between the second terminal of the input transistor and the second terminal of the output transistor.

20. The shift register circuit according to claim 13, further comprising:
a further output unit controllable by the clock signal and electrically connected with the second terminal of the output transistor for controlling the output signal in accordance with the clock signal.
